(19) United States
(12) Patent Application Publication
(10) Pub. No.: US 2023/0140390 A1
(43) Pub. Date: May 4, 2023

(54) Structure and Method of Manufacturing for a Hermetic Housing Enclosure for a Thermal Shock Proof, Zero Thermal Gradient Imaging or Sensing Core

(71) Applicant: T-Smart Systems LLC, Northville, MI (US)

(72) Inventors: Bryan Keith Patmon, Singapore (SG); Wei Kiong Tan, Singapore (SG)

(73) Assignee: T-Smart Systems LLC, Northville, MI (US)

(21) Appl. No.: 17/918,850

(22) PCT Filed: Apr. 12, 2021
(86) PCT No.: PCT/IB2021/000254

§ 371 Date: Oct. 13, 2022

Related U.S. Application Data
(60) Provisional application No. 63/008,882, filed on Apr. 13, 2020.

(51) Int. Cl. G01J 5/16; G01J 5/04; G01J 5/0806; G01J 5/22

(52) U.S. Cl. CPC G01J 5/16; G01J 5/044; G01J 5/045; G01J 5/0806; G01J 5/22; G01J 2005/0077

(57) ABSTRACT

There is disclosed a structure and the manufacturing method for packaging for thermopile or equivalent thermal sensing elements of single orientation, 1D arrays and 2D arrays used for thermal or equivalent media sensing. The sensing core has a primary use as a detection core, and accessory use for improved thermal stability through maximizing the flow of heat energy, through the various packaging constituents to achieve a zero thermal gradient effect. The core package comprises of a substrate, a heat spreader for the thermal sensor, an external housing material manufactured from a wafer fabrication process, and an optics of a silicon wafer and other optical components that is attached to the external housing enclosure using wafer level processing. The external housing enclosure can be scaled to a layered architecture into distinct layers that are stacked vertically on top of each other to make for a multi-lens package.

### CROSS-REFERENCE TO RELATED APPLICATIONS

This application claims the benefit of U.S. Provisional Application Ser. No. 63/008,882 filed Apr. 13, 2020 incorporated herein in its entirety.

### BACKGROUND

The following relates generally to thermal sensing, and more specifically to packaging structures for thermal sensing elements. The thermal elements are usually housed in a structure to protect thermal sensing elements and to provide an environment where thermal shock is minimized.

Sensing devices or an instruments may include one or more sensors (e.g., thermal imaging sensors, image sensors, cameras, etc.) for recording or capturing information, which may be stored locally or transmitted to another device. For example, an image sensor may capture visual information using one or more photosensitive elements that may be tuned for sensitivity to a visible spectrum of electromagnetic radiation. As another example, a thermal imaging sensor may capture thermal imaging information using one or more photosensitive elements (e.g., or thermo-optic elements) that may generally be tuned for sensitivity to some operating wavelength (e.g., such as an infrared (IR) spectrum or long-infrared (long-IR) spectrum of electromagnetic radiation, depending on the radiation being detected). The resolution of captured information may be measured in pixels, where each pixel may relate an independent piece of captured information. In some cases, each pixel may thus correspond to one component of, for example, a two-dimensional (2D) Fourier transform of an image or a heatmap. Computation methods may use the pixel information to reconstruct image information or thermal information captured by the sensor.

It has been a problem that thermal image sensors in such sensing devices or instruments may lose accuracy or sensitivity if subjected to thermal shock such as changing temperatures in the operating environment. In addition there is a need for a simplified design of a hermetically sealed housing that allows for high-volume manufacturing at low cost of the wafer scale packaging of the wafer level optics, for visual or thermal imaging sensors or detectors with the micro-machined wafer level enclosure. Such an enclosure should provide reduced thermal shock to the image sensor via the insulating package to enhance the thermal stability of the thermal or visual imaging core or detector due to reduced influence from external environment. An optimal thermal environment improves the product performance for higher frame rates without compromise to image quality for imagers

### SUMMARY

In one aspect, an apparatus, system, and method for thermal sensing element packaging are described. One or more embodiments of the apparatus, system, and method include a thermally insulated hermetic housing enclosure having a heat reflective coating, where the housing enclosure is affixed to, and is in sealing relation with, a first foundation surface. In one or more embodiments, the housing enclosure has a lens affixed to, and in sealing relation with, the housing enclosure opposite to, and in spaced relation from, the first foundation surface. One or more embodiments further include a thermal imaging sensor located within the housing enclosure. The thermal imaging sensor is equipped with a transparent vacuum cap at a first side of the thermal imaging sensor and the thermal imaging sensor is affixed to a heat spreader at a second side of the thermal imaging sensor opposite the first side, the heat spreader affixed to the first side of the foundation. The thermal imaging sensor is sensitive to light and has input/output (I/O) connectors in electrical connection with thermistors. The thermal imaging sensor is further electrically connected to a controller having memory with instructions to process information received from the thermal imaging sensor.

A method, apparatus, non-transitory computer readable medium, and system for packaging for thermal sensing elements are described. One or more embodiments of the method, apparatus, non-transitory computer readable medium, and system include forming an external housing from a wafer processing compatible material of suitable high thermal conductivity in a repeated sequential process to form microlayers, and forming a micro cavity in each microlayer of the external housing. One or more embodiments include applying a thermal reflective layer to the enclosure of the microlayer, affixing a lens to the enclosure of each the microlayer at a first end of the enclosure, and assembling the microlayers into a housing with an enclosure. One or more embodiments further include affixing a thermal sensor with a transparent vacuum cover at a first surface the sensor to a first surface of a heat spreader on a second surface of the thermal sensor opposite the first surface of the sensor, and affixing the heat spreader at a second surface of the heat spreader to a first surface of a substrate. The sensor is electrically connected to a controller through the substrate, where the substrate is further equipped with at least one thermal conduction path to conduct heat from the sensor. One or more embodiments further include affixing the housing to the substrate so the thermal sensor is within the enclosure and overlaid by the lens and sealing the housing to the substrate.

An apparatus, system, and method for packaging for thermal sensing elements are described. One or more embodiments of the apparatus, system, and method include a substrate forming the foundation where a thermal imaging sensor, a microprocessor, or a microcontroller for data processing are connected. One or more embodiments further include a heat spreader where the image sensor is mounted (e.g., where the heat spreader is bonded to the substrate) and a plurality of external housing, where each external housing has a bonded lens.

### BRIEF DESCRIPTION OF THE DRAWINGS

FIG. 1 shows an example of a bonded imaging sensor structure according to aspects of the present disclosure.

FIG. 2 shows an example of a single lens packaging structure according to aspects of the present disclosure.

FIG. 3 shows an example of a dual lens packaging structure according to aspects of the present disclosure.

FIG. 4 shows an example of a process for packaging for thermal sensing elements according to aspects of the present disclosure.

### DETAILED DESCRIPTION

Embodiments described herein provide structures and manufacturing methods for packaging for thermopile or equivalent thermal sensing elements of single orientation, 1D arrays and 2D arrays used for thermal or equivalent media sensing. A sensing core may have a primary use as a detection core, as well as an accessory use for improved thermal stability through maximizing the flow of heat energy through the various packaging constituents to achieve a zero thermal gradient effect. The insulative enclosure provides for a highly effective environment protection against thermal shock.

A method of manufacturing is described that allows efficient combining of specific materials for establishing optimum heat transfer, thermal gradient management, and thermal shock protection for thermal imaging and thermal sensing cores. The core package comprises a substrate, a heat spreader for the thermal sensor, and an external housing material manufactured from a wafer fabrication process (e.g., which is a procedure composed of many repeated sequential processes to produce a complete miniaturized mechanical or electro-mechanical elements, such as devices and structures, that are made using the techniques of a microfabrication compatible process). The core package further includes insulating/conductive material and a optics of a silicon wafer and other optical components that are attached to the external housing enclosure using wafer level processing. The external housing enclosure can be scaled to a layered architecture, which can be a grouping of related functionality within the application into distinct layers that are stacked vertically on top of each other to provide a multi-lens package.

In contrast to other packaging methods, embodiments described herein allow for wafer-level packaging, which includes extending the wafer fabrication processes to optimize the thermal gradient at the thermal sensor through interfacing and interconnection of materials and the device protection processes. Techniques described herein provide a true wafer level processing of the packaging of a thermal imaging or sensing core, while offering an environment that shields the thermal sensor and associated components from any thermal shock. Techniques described herein further provide the optimal thermal environment for high framing rates without compromise to image or sensing quality.

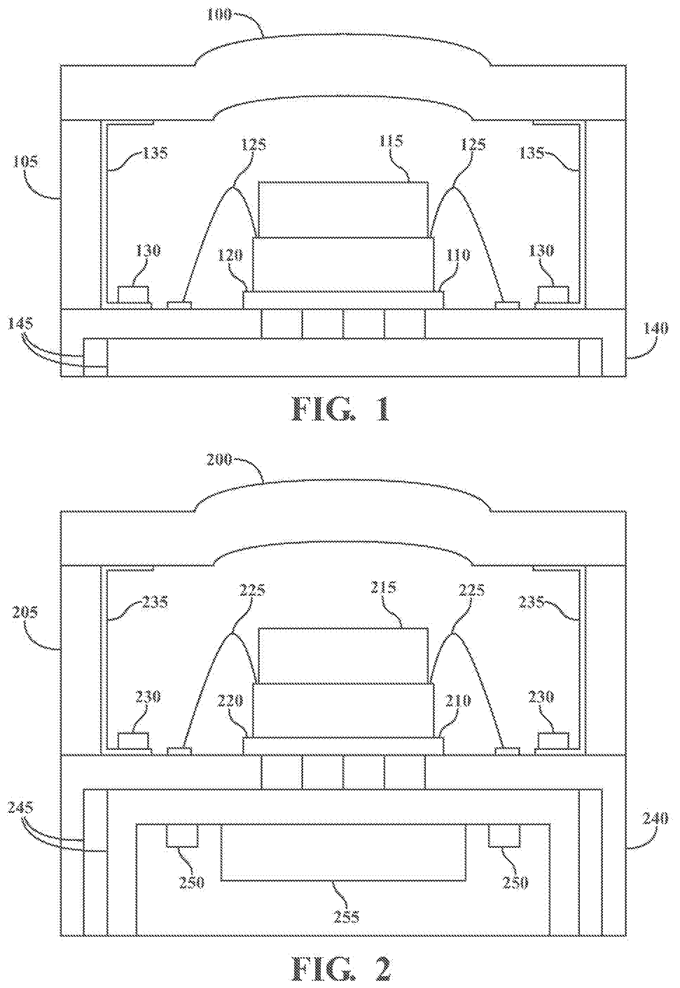

FIG. 1 shows an example of a bonded imaging sensor structure according to aspects of the present disclosure. The example shown includes lens 100, housing enclosure 105, thermal imaging sensor 110, vacuum cap 115, heat spreader 120, input/output (I/O) connectors 125, thermistors 130, HR coating 135, substrate 140, and thermal conduction paths 145. FIG. 1 may illustrate aspects of a bonded imaging sensor structure.

A bonded imaging sensor structure (e.g., aspects of a single lens packaging structure) may include lens 100 (e.g., or a flat window layer) fabricated from a suitable material for the operating wavelength, where the operating wavelength depends on the radiation being detected, the electromagnetic spectrum being captured, etc. The bonded imaging also includes a housing enclosure 105, which may be fabricated from glass or other suitable insulating material with a micromachined cavity. The bonded imaging sensor structure may further include a thermal imaging sensor 110 (e.g., a thermal imaging or sensor chip), a transparent vacuum cap, a heat spreader 120, connecting I/O wires (e.g., I/O connectors 125), thermistors 130, and metal coating functioning as a high reflectivity (HR) coating 135. The bonded imaging sensor structure may further include substrate 140 and thermal conduction paths 145.

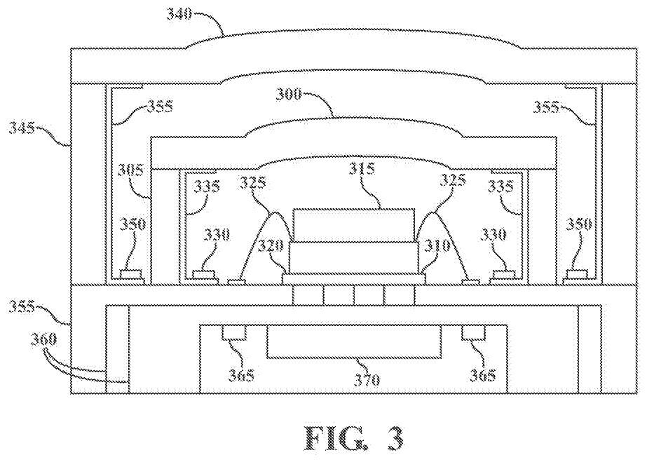

In some embodiments, the bonded imaging sensor structure of FIG. 1 may be bonded to a substrate 140, where the substrate 140 functions as both the base of the overall package and the electrical connection paths of the I/O pins (e.g., as further described herein, for example, with reference to FIG. 2). In other embodiments (e.g., where the structure is applied to a sensor with external controlling electronics), the structure may be as depicted in FIG. 1 (e.g., where a controller, such as an application specific integrated circuit (ASIC) or microcontroller, is not integrated directly into the structure).

The lens 100 (or window) is fabricated on the wafer level from a suitable material for the operating wavelength (e.g., silicon (Si) or germanium (Ge)) and is antireflection (AR) coated on both top and bottom surfaces to maximize transmission of intended radiation. The external housing enclosure 105 may start out as a glass (or other suitable material) wafer and cavities of suitable dimensions are micromachined into the wafer. The glass wafer is then subjected to a metal sputtering process that coats the internal of the cavity. The metal coating will be of a suitable material that functions both as a HR coating and to aid in the speed of temperature equalization between the lens 100 and the monitoring thermistors 130. This helps to improve the lens 100 temperature tracking time constant at the thermistors 130. The lens 100 wafer and the enclosure wafer are then bonded together using either a eutectic or metallic bonding process.

The thermal imaging sensor 110 includes of a plurality of photo sensitive pixels, and may be integrated with a complementary metal-oxide-semiconductor (CMOS) readout integrated circuit (IC), sealed with a vacuum cap. The sealing between the thermal imaging sensor 110 and the vacuum cap is carried out in a suitably high vacuum level to ensure minimum heat loss path. The vacuum cap is fabricated from a suitable transparent material which may be of silicon or germanium or glass, or any other suitable material dependent on the intended wavelength window of operation. The sealing process is carried out at wafer level before singulation. The thermal imaging sensor 110 is then bonded (e.g., eutectic bonded) to the heat spreader 120 (e.g., material with suitable thermal properties to spread heat).

A thermal imaging sensor 110 may capture thermal imaging information using one or more photosensitive elements (e.g., or thermo-optic elements) that may generally be tuned for sensitivity to some operating wavelength (e.g., such as an infrared (IR) spectrum or long-infrared (long-IR) spectrum of electromagnetic radiation, depending on the radiation being detected). The resolution of captured information may be measured in pixels, where each pixel may relate an independent piece of captured information. In digital imaging, a pixel (or picture element) refers to a small (e.g., the smallest) addressable element in a display device, and the smallest controllable element of a picture represented on the device. In some cases, each pixel may represent a sample of captured information. The color and intensity of each pixel may be variable. In color imaging systems, a color may be represented by three or four component intensities such as red, green, and blue, or cyan, magenta, yellow, and black. In thermal imaging systems, temperature may be represented by color intensities (e.g., such as an intensity range from dark or black, to orange or yellow, to bright white). In some cases, each pixel may thus correspond to one component of, for example, a two-dimensional (2D) Fourier transform of a heatmap, image, radiation information, etc. Computation methods may use the pixel information to reconstruct image information or thermal information captured by the sensor.

Lens 100 is an example of, or includes aspects of, the corresponding element described with reference to FIG. 2. Housing enclosure 105 is an example of, or includes aspects of, the corresponding element described with reference to FIG. 2. Thermal imaging sensor 110 is an example of, or includes aspects of, the corresponding element described with reference to FIGS. 2 and 3. Vacuum cap 115 is an example of, or includes aspects of, the corresponding element described with reference to FIGS. 2 and 3. Heat spreader 120 is an example of, or includes aspects of, the corresponding element described with reference to FIGS. 2 and 3. I/O connectors 125 is an example of, or includes aspects of, the corresponding element described with reference to FIGS. 2 and 3. Thermistors 130 is an example of, or includes aspects of, the corresponding element described with reference to FIG. 2. HR coating 135 is an example of, or includes aspects of, the corresponding element described with reference to FIGS. 2 and 3. substrate 140 is an example of, or includes aspects of, the corresponding element described with reference to FIGS. 2 and 3. Thermal conduction paths 145 is an example of, or includes aspects of, the corresponding element described with reference to FIGS. 2 and 3.

FIG. 2 shows an example of a single lens 200 packaging structure according to aspects of the present disclosure. The example shown includes lens 200, housing enclosure 205, thermal imaging sensor 210, vacuum cap 215, heat spreader 220, I/O connectors 225, thermistors 230, HR coating 235, substrate 240, thermal conduction paths 245, passives 250, and controller 255. In some aspects, FIG. 2 may illustrate the bonded imaging sensor structure of FIG. 1 when bonded (e.g., eutectic bonded) to a substrate 240, where the substrate 240 functions as both the base of the overall package and the electrical connection paths of the I/O pins. The substrate 240 includes a sea of thermal vias, which functions as effective thermal conduction paths 245 from the thermal imaging sensor 210 to the external environment for proper heat management.

An example of a single lens packaging structure (e.g., shown in FIG. 2) may include lens 200 (e.g., a flat window layer), fabricated from a suitable material for the operating wavelength, as well as a housing enclosure 205, which is fabricated from glass or other suitable insulating material with a micromachined cavity. The bonded imaging sensor structure may further include a thermal imaging sensor 210 (e.g., or sensor chip), a transparent vacuum cap, a heat spreader 220, connecting I/O wires (e.g. I/O connectors 225), thermistors 230, and metal coating functioning as a HR coating 235. As shown in FIG. 2, the structure of a single lens 200 packaging further includes a substrate 240 (e.g., functioning as the foundation of the structure), thermal conduction paths 245, passives 250, and a controller 255 for signal processing purposes(e.g., which may include an ASIC, a microcontroller (MCU), a microprocessor, etc.).

A controller 255 (e.g., or processor) is an intelligent hardware device, (e.g., a general-purpose processing component, a digital signal processor (DSP), a central processing unit (CPU), a graphics processing unit (GPU), a microcontroller, an ASIC, a field programmable gate array (FPGA), a programmable logic device, a discrete gate or transistor logic component, a discrete hardware component, or any combination thereof). In some cases, the controller 255 is configured to operate a memory array using a memory controller. In other cases, a memory controller is integrated into the controller 255. In some cases, the controller 255 is configured to execute computer-readable instructions stored in a memory to perform various functions. In some embodiments, a controller 255 includes special purpose components for modem processing, baseband processing, digital signal processing, or transmission processing.

I/O connectors 225 may provide content and data to control circuitry, which includes processing circuitry and storage. Control circuitry may be used to send and receive commands, requests, and other suitable data using I/O connectors 225. I/O connectors 225 may connect control circuitry (and specifically processing circuitry) to one or more communications paths. I/O functions may be provided by one or more of these communications paths. Control circuitry may be based on any suitable processing circuitry such as processing circuitry. Processing circuitry may include circuitry based on one or more microprocessors, microcontrollers, digital signal processors, programmable logic devices, FPGAs, ASICs, etc., and may include a multi-core processor (e.g., dual-core, quadcore, hexa-core, or any suitable number of cores) or supercomputer. In some embodiments, processing circuitry may be distributed across multiple separate processors or processing units, for example, multiple of the same type, or different type, of processing units.

Before the bonding of the substrate 240 to the bonded imaging sensor structure, the controller 255 (e.g., which may be gold bumped) is first flip chip mounted to backside of the substrate 240. The passives 250 (e.g., which may include capacitors and resistors for the proper operation of the controller 255) are mounted to the substrate 240 (e.g., the ceramic substrate 240). I/O connectors 225 (e.g., wire bonding) is then carried out to form the connections between the thermal imaging sensor 210 and I/O of the ceramic substrate 240. Finally, the enclosure structure is bonded to the substrate 240 under a suitable vacuum condition or a filling gas environment. This effectively reduces any heat loss during transmission from the lens 200 to the thermal imaging sensor 210 while at the same time providing for an ideal shield against any thermal shock at the thermal imaging sensor 210 from external temperature fluctuations.

The techniques described herein provide a structure and method of manufacturing for a single layer structure (e.g., or multi-layer structure, as described in more detail herein, for example, with reference to FIG. 3) to act as a protective hermetic housing, while providing an environmental barrier (e.g., an environmental barrier which creates a protection against sudden ambient temperature changes while at the same time providing a zero thermal gradient under the thermal sensor).

As described herein, a packaging structure may include a thermal detection device (e.g., a thermal imaging sensor 210), which may provide thermal detection, thermal imaging, or thermal spectroscopy capability, through a plurality of sensor pixels in the visible or the IR range. The packaging structure may further include an integrated readout IC for the readout of signals from the sensor pixels, as well as a controller 255 for the purpose of image processing or data processing of the readout signals and other auxiliary functions (e.g., such as an ASIC, a MCU, a microprocessor unit, etc.). The packaging structure may also include a substrate 240 with sufficiently low thermal conductivity that provides for the interconnect between the thermal imaging sensor 210 and the processing unit or the external I/O points.

According to some embodiments, the packaging structure may include micromachined enclosures (e.g., housing enclosure 205) that are formed by the removal of small amounts of material for a specific design as required for the sensing elements, and that are subsequently bonded by a optically protective layer, which is manufactured through Wafer-Level Optics (WLO) enabling miniaturized optics to be incorporated at the wafer level and subsequently singulated. The housing enclosures 205 seal the overall package and provide for thermal shock shielding. The packaging structure may further include AR coated lens 200 (e.g., or a transparent window layer) that is bonded to the housing enclosure 205.

Moreover, techniques described herein may further provide for additional (e.g., multiple) enclosures with bonded AR coated lens 200 as desired for multi-lens thermal detection, multi-lens 200 imaging, or a multi-lens sensing core (e.g., as described in more detail herein, for example, with reference to FIG. 3). In such implementations, the one or more housing enclosures 205 may be sealed under vacuum conditions of suitably low pressure or with any suitable gas environment.

Embodiments described herein may provide for minimum loss in the heat transmission path through the package to the image sensor. Further, the efficient design described herein allows for high-volume manufacturing at low cost of the wafer scale packaging of the wafer level optics, for visual imaging sensors, thermal imaging sensors 210, visual or thermal imaging detectors, etc. (e.g., with the micromachined wafer level enclosure). Additionally, thermal shock to the thermal imaging sensor 210 may be reduced via the insulating package, and the thermal stability of the packing structure (e.g., the thermal imaging core, visual imaging core, detector, etc.) may be enhanced due to reduced influence from the external environment. Some embodiments described herein provide for an improved (e.g., optimal) thermal environment, for example, which may improve the product performance for higher frame rates without compromise to image quality (e.g., for imagers).

An apparatus for packaging for thermal sensing elements is described. One or more embodiments of the apparatus include a thermally insulated hermetic housing enclosure 205 having a heat reflective coating. The housing enclosure 205 is affixed to, and is in sealing relation with, a first foundation surface. A lens 200 is affixed to, and is in sealing relation with, the housing enclosure 205 opposite to, and in spaced relation from, the first foundation surface. A thermal imaging sensor 210 is located within the housing enclosure 205. The thermal imaging sensor 210 is equipped with a transparent vacuum cap at a first side of the thermal imaging sensor 210, and the thermal imaging sensor 210 is affixed to a heat spreader 220 at a second side of the thermal imaging sensor 210 opposite the first side of the thermal imaging sensor 210. The heat spreader 220 is affixed to the first foundation surface. The thermal imaging sensor 210 is sensitive to light and has I/O connectors in electrical connection with thermistors 230. The thermal imaging sensor 210 is electrically connected to a controller 255 having memory with instructions to process information received from the thermal imaging sensor 210.

A system for thermal detection is described, the system comprising a thermally insulated hermetic housing enclosure 205 and a thermal imaging sensor 210. The thermally insulated hermetic housing enclosure 205 has a heat reflective coating, where the housing enclosure 205 is affixed to, and is in sealing relation with, a first foundation surface. Further, a lens 200 is affixed to, and is in sealing relation with, the housing enclosure 205 opposite to, and in spaced relation from, the first foundation surface. The thermal imaging sensor 210 is located within the housing enclosure 205, and the thermal imaging sensor 210 is equipped with a transparent vacuum cap at a first side of the thermal imaging sensor 210 and is affixed to a heat spreader 220 at a second side of the thermal imaging sensor 210 opposite the first side. The heat spreader 220 is affixed to the first side of the foundation. The thermal imaging sensor 210 is sensitive to light and has I/O connectors 225 in electrical connection with thermistors 230. The thermal imaging sensor 210 is electrically connected to a controller 255 having memory with instructions to process information received from the thermal imaging sensor 210.

A method of manufacturing a thermal detection device is described. The method includes manufacturing a thermally insulated hermetic housing enclosure 205 having a heat reflective coating, where the housing enclosure 205 is affixed to, and is in sealing relation with, a first foundation surface and the housing enclosure 205 has a lens 200 affixed to, and is in sealing relation with, the housing enclosure 205 opposite to, and in spaced relation from, the first foundation surface. The method of manufacturing the thermal detection device further includes manufacturing a thermal imaging sensor 210 located within the housing enclosure 205; the thermal imaging sensor 210 equipped with a transparent vacuum cap at a first side of the thermal imaging sensor 210 and affixed to a heat spreader 220 at a second side of the thermal imaging sensor 210 opposite the first side, the heat spreader 220 affixed to the first side of the foundation; the thermal imaging sensor 210 sensitive to light and having I/O connectors 225 in electrical connection with thermistors 230; the thermal imaging sensor 210 further electrically connected to a controller 255 having memory with instructions to process information received from the thermal imaging sensor 210.

In some examples, the thermal imaging sensor 210 includes at least one sensor pixel sensitive to infrared light. In some examples, the thermal imaging sensor 210 has a plurality of sensor pixels sensitive to infrared light and capable of thermal detection, thermal imaging, or thermal spectroscopy. In some examples, the controller 255 is a read out integrated circuit for readout of signals from the thermal imaging sensor 210. In some examples, the controller 255 is an ASIC, MCU, or microprocessor unit for image or data processing of readout signals from the thermal imaging sensor 210. In some examples, the heat spreader 220 is a heat conductor with a sufficiently high thermal conductivity. In some examples, the lens 200 has an anti-reflection coating.

In some examples, the lens 200 is made of glass, silicon, germanium, and mixtures thereof. In some examples, the transparent vacuum cap is made of glass, silicon, germanium, and mixtures thereof. In some examples, the heat reflective coating is a metal. In some examples, the transparent reflective cap has an anti-reflection function. In some examples, the controller 255 is affixed to a second surface of the foundation opposite to the first foundation side. In some examples, the thermal reflective layer is a metal. In some examples, the housing enclosure 205 is a glass wafer having cavities of suitable dimension formed therein. In some examples, the lens 200 and the housing enclosure 205 are bonded together using a eutectic or metallic bonding process. In some examples, the transparent vacuum layer is vacuum sealed to the sensor at a wafer level before wafer singulation. In some examples, the foundation further includes at least one thermal conduction path from the thermal imaging sensor 210 to an external environment. In some examples, the housing enclosure 205 is bonded to the foundation under vacuum condition. In some examples, the housing enclosure 205 is bonded to the foundation in the presence of a noble gas.

Lens 200 is an example of, or includes aspects of, the corresponding element described with reference to FIG. 1. Housing enclosure 205 is an example of, or includes aspects of, the corresponding element described with reference to FIG. 1. Thermal imaging sensor 210 is an example of, or includes aspects of, the corresponding element described with reference to FIGS. 1 and 3. Vacuum cap 215 is an example of, or includes aspects of, the corresponding element described with reference to FIGS. 1 and 3. Heat spreader 220 is an example of, or includes aspects of, the corresponding element described with reference to FIGS. 1 and 3. I/O connectors 225 is an example of, or includes aspects of, the corresponding element described with reference to FIGS. 1 and 3. Thermistors 230 is an example of, or includes aspects of, the corresponding element described with reference to FIG. 1. HR coating 235 is an example of, or includes aspects of, the corresponding element described with reference to FIGS. 1 and 3. Substrate 240 is an example of, or includes aspects of, the corresponding element described with reference to FIGS. 1 and 3. Thermal conduction paths 245 is an example of, or includes aspects of, the corresponding element described with reference to FIGS. 1 and 3. Passives 250 is an example of, or includes aspects of, the corresponding element described with reference to FIG. 3. Controller 255 is an example of, or includes aspects of, the corresponding element described with reference to FIG. 3.

FIG. 3 shows an example of a dual lens packaging structure according to aspects of the present disclosure. The example shown includes first lens 300, first housing enclosure 305, second lens 340, second housing enclosure 345, substrate 355, thermal conduction paths 360, passives 365, and controller 370. FIG. 3 illustrates aspects of how packaging structure embodiments described herein may be extended to multi-lens systems. For instance, the example shown in FIG. 3 may include a structure of FIG. 2 in addition to a second housing enclosure 345, second lens 340, and lens temperature tracking thermistors 350 for second lens 340. The bonded structure of the first housing enclosure 305 and the second housing enclosure 345 is bonded to the substrate 355 (e.g., at the last stage under suitable vacuum conditions). The advantage of such a structure is the additional vacuum stage which provides further thermal shock protection to the thermal imaging sensor 310.

Accordingly, techniques described herein may generally provide for additional (e.g., multiple) housing enclosures with bonded AR coated lens as desired for multi-lens thermal detection, multi-lens imaging, or a multi-lens sensing core. In such implementations, the housing enclosures may be sealed under vacuum conditions of suitably low pressure or with any suitable gas environment. For instance, in FIG. 3, the first housing enclosure 305 and the second housing enclosure 345 may be sealed under vacuum conditions of suitably low pressure or with any suitable gas environment.

A packaging for thermal sensing elements is described. One or more embodiments of the packaging include a substrate 355 forming the foundation where a thermal imaging sensor 310, a microprocessor, or a microcontroller (e.g., a controller 370) for data processing are connected. The packaging further includes a heat spreader 320 where the thermal imaging sensor 310 is mounted, where the heat spreader 320 is bonded to the substrate 355, and a plurality of external housing, where each external housing has a bonded lens. For instance, in the example of FIG. 3, first housing enclosure 305 has first bonded lens 300, and second housing enclosure 345 has second bonded lens 340.

In some examples, the substrate 355 is of a suitably low thermal conducting material, with embedded electrical interconnects for the interconnection between the thermal imaging sensor 310, the microprocessor or microcontroller for image processing and the related passive components, and with a sea of thermal vias (e.g., I/O connectors 325) filled with suitable thermally conductive material for sinking of heat to external environment. In some examples, the thermal imaging sensor 310 is eutectic bonded to the heat spreader 320 where the material of the heat spreader 320 is of a high thermal conductivity while having sufficiently low expansion coefficient to not impact the focus of the image within the operating temperature range. In some examples, the heat spreader 320 is further eutectic bonded to the substrate 355, with the thermal vias (e.g., I/O connectors 325) in direct contact with the heat spreader 320.

In some examples, the external housing is fabricated from wafer processing compatible material which is of significantly low thermal conductivity and optical lens or window layer bonded on the top of the housing. In some examples, the external housing comprises of a wafer processing compatible material and a cavity where cavities are micromachined at wafer level and the attached lens or window layer is anti-reflection coated. In some examples, the external housing can be scaled to multiple layers as needed to cater for a multiple lens imaging or sensing core (e.g., the packaging may include first housing enclosure 305 and first lens 300, second housing enclosure 345 and second lens 340, etc.). In some examples, the plurality of the external housing is hermetically bonded completely around the periphery of substrate 355 of geometric shape under vacuum of suitably low pressure or in a suitable gas environment.

In one embodiment, first housing enclosure 305 includes thermal imaging sensor 310, vacuum cap 315, heat spreader 320, I/O connectors 325, thermistors 330 for first lens 300, and HR coating 335. First housing enclosure 305, thermal imaging sensor 310, vacuum cap 315, heat spreader 320, I/O connectors 325, thermistors 330 for first lens 300, and HR coating 335 each may be examples of, or may each include aspects of, the respective corresponding elements described with reference to FIGS. 1 and 2.

In one embodiment, second housing enclosure 345 includes thermistors 350 for second lens 340. Substrate 355 is an example of, or includes aspects of, the corresponding element described with reference to FIGS. 1 and 2. Thermal conduction paths 360 is an example of, or includes aspects of, the corresponding element described with reference to FIGS. 1 and 2. Passives 365 is an example of, or includes aspects of, the corresponding element described with reference to FIG. 2. Controller 370 is an example of, or includes aspects of, the corresponding element described with reference to FIG. 2.

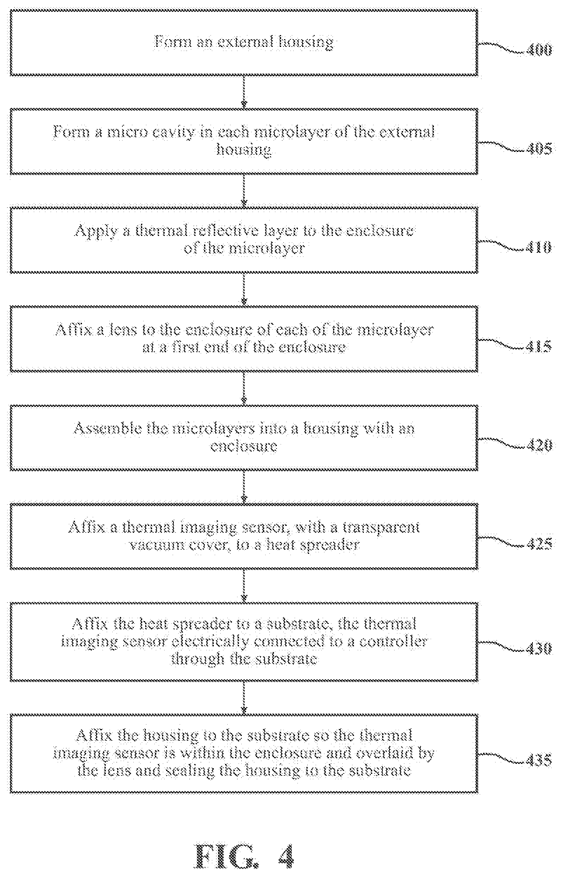

FIG. 4 shows an example of a process for packaging for thermal sensing elements according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

A method of manufacturing packaging for thermopile thermal sensing elements of a single orientation, 1D or 2D array for thermal media sensing is described. One or more embodiments of the method include forming an external housing from a wafer processing compatible material of suitable high thermal conductivity in a repeated sequential process to form microlayers, and forming a micro cavity in each microlayer of the external housing. The method may further include applying a thermal reflective layer to the enclosure of the microlayer, affixing a lens to the enclosure of each the microlayer at a first end of the enclosure, and assembling the microlayers into a housing with an enclosure. The method may further include affixing a thermal sensor with a transparent vacuum cover at a first surface the sensor to a first surface of a heat spreader on a second surface of the thermal sensor opposite the first surface of the sensor and affixing the heat spreader at a second surface of the heat spreader to a first surface of a substrate, the sensor electrically connected to a controller through the substrate. The substrate is further equipped with at least one thermal conduction path to conduct heat from the sensor. The method may further include affixing the housing to the substrate, such that the thermal sensor is within the enclosure and overlaid by the lens and sealing the housing to the substrate.

At operation 400, the system forms an external housing from a wafer processing compatible material of suitable high thermal conductivity in a repeated sequential process to form microlayers. At operation 405, the system forms a micro cavity in each microlayer of the external housing. At operation 410, the system applies a thermal reflective layer to the enclosure of the microlayer. At operation 415, the system affixes a lens to the enclosure of each the microlayer at a first end of the enclosure. At operation 420, the system assembles the microlayers into a housing with an enclosure.

At operation 425, the system affixes a thermal imaging sensor with a transparent vacuum cover at a first surface the thermal imaging sensor to a first surface of a heat spreader on a second surface of the thermal imaging sensor opposite the first surface of the thermal imaging sensor. At operation 430, the system affixes the heat spreader at a second surface of the heat spreader to a first surface of a substrate, the thermal imaging sensor electrically connected to a controller through the substrate, where the substrate is further equipped with at least one thermal conduction path to conduct heat from the thermal imaging sensor. At operation 435, the system affixes the housing to the substrate, such that the thermal imaging sensor is within the enclosure and overlaid by the lens and sealing the housing to the substrate.

In some examples, the housing enclosure is sealed to the substrate under vacuum. In some examples, the housing enclosure is sealed to the substrate in the presence of a noble gas. In some examples, the lens has an antireflective coating. In some examples, the thermal reflective layer is a deposited metal. In some examples, the housing enclosure is formed by micromachining In some examples, the wafer processing compatible material is glass. In some examples, the lens is made of, silicon or geranium, or mixtures thereof. In some examples, the thermal sensor is equipped with at least one pixel sensitive to light energy in an infrared range.

In some examples, the controller is a read out integrated circuit for readout of signals from the thermal sensitive sensor. In some examples, the controller is an ASIC, MCU or microprocessor unit for image or data processing of readout signals from the thermal imaging sensor. In some examples, the lens and the housing enclosure are bonded together using a eutectic or metallic bonding process. In some examples, the transparent vacuum layer is vacuum sealed to the sensor at a wafer level before wafer singulation. In some examples, the controller is affixed to a second surface of the substrate opposite to the first surface of the substrate. In some examples, the multiple housings with a lens may be stacked upon each other.

The description and drawings described herein represent example configurations and do not represent all the implementations within the scope of the claims. For example, the operations and steps may be rearranged, combined, or otherwise modified. Also, structures and devices may be represented in the form of block diagrams to represent the relationship between components and avoid obscuring the described concepts. Similar components or features may have the same name but may have different reference numbers corresponding to different figures.

Some modifications to the disclosure may be readily apparent to those skilled in the art, and the principles defined herein may be applied to other variations without departing from the scope of the disclosure. Thus, the disclosure is not limited to the examples and designs described herein, but is to be accorded the broadest scope consistent with the principles and novel features disclosed herein.

The described systems and methods may be implemented or performed by devices that include a general-purpose processor, a DSP, an ASIC, a FPGA or other programmable logic device, discrete gate or transistor logic, discrete hardware components, or any combination thereof. A general-purpose processor may be a microprocessor, a conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Thus, the functions described herein may be implemented in hardware or software and may be executed by a processor, firmware, or any combination thereof. If implemented in software executed by a processor, the functions may be stored in the form of instructions or code on a computer-readable medium.

Computer-readable media includes both non-transitory computer storage media and communication media including any medium that facilitates transfer of code or data. A non-transitory storage medium may be any available medium that can be accessed by a computer. For example, non-transitory computer-readable media can comprise random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, connecting components may be termed computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or”indicates an inclusive list such that, for example, the list of X, Y, or Z means X or Y or Z or XY or XZ or YZ or XYZ. Also the phrase “based on”is not used to represent a closed set of conditions. For example, a step that is described as “based on condition A”may be based on both condition A and condition B. In other words, the phrase “based on”shall be construed to mean “based at least in part on.”Also, the words “a”or “an”indicate “at least one.”

What is claimed is:

1. A thermal detection device, comprising;
a thermally insulated hermetic housing enclosure; the housing enclosure including a thermally insulated enclosure; the thermally insulated enclosure having a heat reflective coating: the thermally insulated hermetic housing enclosure affixed to and in scaling relation with a first foundation surface and having a lens affixed to and in sealing relation with the housing enclosure opposite to and in spaced relation from the first foundation surface;
a thermal imaging sensor located within the thermally insulated enclosure; the thermal imaging sensor equipped with a transparent vacuum cap at a first side of the thermal imaging sensor and affixed to a heat spreader at a second side of the thermal imaging sensor opposite the first side, the heat spreader affixed to the first side of the foundation; the thermal imaging sensor sensitive to light and having input/output (I/O) connectors in electrical connection with thermistors; the thermal imaging sensor further electrically connected to a controller having memory with instructions to process information received from the thermal imaging sensor.

2. The thermal detection device of claim 1, wherein the thermal imaging sensor includes at least one sensor pixel sensitive to infrared light.

3. The thermal detection device of claim 1, wherein the thermal imaging sensor has a plurality of sensor pixels sensitive to infrared light and capable of thermal detection, imaging or thermal spectroscopy.

4. The thermal detection device of claim 1, wherein the controller is a read out integrated circuit for readout of signals from the infrared sensitive sensor.

5. The thermal detection device of claim 1, wherein the controller is an application specific integrated circuit, micro controller or microprocessor unit for image or data processing of readout signals from the thermal imaging sensor.

6. The thermal detection device of claim 1, wherein the heat spreader is a heat conductor with a sufficiently high thermal conductivity.

7. The thermal detection device of claim 1, wherein the lens has an anti-reflection coating.

8. The thermal detection device of claim 1, wherein the lens is made of glass, silicon, germanium and mixtures thereof.

9. The thermal detection device of claim 1, wherein the transparent vacuum cap is made of glass, silicon, germanium and mixtures thereof.

10. The thermal detection device of claim 1, wherein the heat reflective coating is a metal.

11. The thermal detection device of claim 1, wherein the transparent reflective cap has an anti-reflection function.

12. The thermal detection device of claim 1, wherein the controller is affixed to a second surface of the foundation opposite to the first foundation side.

13. The thermal detection device of claim 1, wherein the thermal reflective layer is a metal.

14. The thermal detection device of claim 1, wherein the external housing enclosure is a glass wafer having cavities of suitable dimension formed therein.

15. The thermal detection device of claim 1, wherein the lens and enclosure are bonded together using a eutectic or metallic bonding process.

16. The thermal detection device of claim 1, wherein the transparent vacuum layer is vacuum sealed to the sensor at a wafer level before wafer singulation.

17. The thermal detection device of claim 1, wherein the foundation further includes at least one thermal conduction path from the sensor chip to an external environment.

18. The thermal detection device of claim 1, wherein the enclosure is bonded to the foundation under vacuum condition.

19. The thermal detection device of claim 1, wherein the enclosure is bonded to the foundation in the presence of a noble gas.

20. A method of manufacturing packaging for thermopile thermal sensing elements of a single orientation, 1D or 2D array for thermal media sensing; comprising;
forming an external housing from a wafer processing compatible material of suitable high thermal conductivity in a repeated sequential process to form micro layers;
forming a micro cavity in each micro layer of the external housing;
applying a thermal reflective layer to the enclosure of the microlayer;
affixing a lens to the enclosure of each the microlayer at a first end of the enclosure;
assembling the micro layers into a housing with an enclosure;
affixing a thermal sensor with a transparent vacuum cover at a first surface the sensor to a first surface of a heat spreader on a second surface of the thermal sensor opposite the first surface of the sensor, and affixing the heat spreader at a second surface of the heat spreader to a first surface of a substrate, the sensor electrically connected to a controller through the substrate; the substrate further equipped with at least one thermal conduction path to conduct heat from the sensor;
affixing the housing to the substrate so the thermal sensor is within the enclosure and overlaid by the lens and sealing the housing to the substrate.

21. The method of claim 20, wherein the housing enclosure is sealed to the substrate under vacuum.

22. The method of claim 20, wherein the housing enclosure is sealed to the substrate in the presence of a noble gas.

23. The method of claim 20, wherein the lens has an antireflective coating.

24. The method of claim 20, wherein the thermal reflective layer is a deposited metal.

25. The method of claim 20, wherein the enclosure is formed by micromachining.

26. The method of claim 20, wherein the wafer processing compatible material is glass.

27. The method of claim 20, wherein the lens is made of, silicon or geranium, or mixtures thereof.

28. The method of claim 20, wherein the thermal sensor is equipped with at least one pixel sensitive to light energy in the infrared range.

29. The method of claim 20, wherein the controller is a read out integrated circuit for readout of signals from the thermal sensitive sensor.

30. The method of claim 20, wherein the controller is an application specific integrated circuit, micro controller or microprocessor unit for image or data processing of readout signals from the thermal imaging sensor.

31. The method of claim 20, wherein the lens and enclosure are bonded together using a eutectic or metallic bonding process.

32. The method of claim 20, wherein the transparent vacuum layer is vacuum sealed to the sensor at a wafer level before wafer singulation.

33. The method of claim 20, wherein the controller is affixed to a second surface of the foundation opposite to the first foundation side.

34. The method of claim 33, wherein multiple housings with a lens may be stacked upon each other.
